(19) United States
(12) Patent Application Publication
(10) Pub. No.: US 2026/0068586 A1
(43) Pub. Date: Mar. 5, 2026

(54) TRANSMISSIVE AND ABSORPTIVE MASS ARRANGEMENTS FOR LIFT FRAMES, AND RELATED PROCESSING CHAMBERS, CHAMBER KITS, AND METHODS

(71) Applicant: Applied Materials, Inc., Santa Clara, CA (US)

(72) Inventors: Chen-Yao CHAO, Santa Clara, CA (US); Seng-Hoe TAN, Singapore (SG); Kazuyoshi KOBASHI, Santa Clara, CA (US); Ryan Sungbin HU, Santa Clara, CA (US); Masato ISHII, Sunnyvale, CA (US); Kuan Chien SHEN, Sunnyvale, CA (US); Zang KEYAN, Singapore (SG); Ribhu GAUTAM, Sunnyvale, CA (US)

(21) Appl. No.: 18/821,792

(22) Filed: Aug. 30, 2024

(51) Int. Cl. H01L 21/67; H01L 21/673

(52) U.S. Cl. CPC H01L 21/6719

(57) ABSTRACT

Embodiments of the present disclosure generally relate to mass arrangements for lift frames, and related substrate processing chambers, chamber kits, and methods. In one or more embodiments, a processing chamber includes a chamber body including a plurality of gas inject passages formed in the chamber body. The chamber body at least partially defines an internal volume. The processing chamber includes a substrate support assembly positioned in the internal volume. The substrate support assembly includes a lift frame. The lift frame includes a plurality of arms and a ring supported by the plurality of arms. The lift frame includes a plurality of sections azimuthally spaced from each other. The plurality of sections have a different transmissivity than the ring.

### BACKGROUND

### Field

Embodiments of the present disclosure generally relate to transmissive and absorptive mass arrangements for lift frames, and related substrate processing chambers, chamber kits, and methods.

### Description of the Related Art

Semiconductor substrates are processed for a wide variety of applications, including the fabrication of integrated devices and microdevices. During processing, various parameters can affect the uniformity of material deposited on the substrate. For example, the temperature of the substrate and/or temperature(s) of processing chamber component(s) can affect deposition uniformity. As another example, the atomic structure orientation (e.g., crystal orientation) along an outer edge of a substrate can vary, which can cause non-uniformities in growth rates.

It can be difficult to adjust parameters (such as processing temperatures, gas flow rates and gas pressures) for deposition uniformity. Rotation of the substrate, if used, can exacerbate adjustment difficulties.

Therefore, a need exists for improved processing chambers.

### SUMMARY

Embodiments of the present disclosure generally relate to transmissive and absorptive mass arrangements for lift frames, and related substrate processing chambers, chamber kits, and methods.

In one or more embodiments, a processing chamber includes a chamber body including a plurality of gas inject passages formed in the chamber body. The chamber body at least partially defines an internal volume. The processing chamber includes a substrate support assembly positioned in the internal volume. The substrate support assembly includes a lift frame. The lift frame includes a plurality of arms and a ring supported by the plurality of arms. The lift frame includes a plurality of sections on the ring. The plurality of sections are azimuthally spaced from each other. The plurality of sections have a different transmissivity than the ring.

In one or more embodiments, a lift frame for positioning in a processing chamber includes a shaft and a plate supported by the shaft. The lift frame includes a plurality of arms extending relative to the plate, and one or more sections on the plate. The one or more sections have a different transmissivity than the plate.

In one or more embodiments, a lift frame for positioning in a processing chamber includes a shaft and a plurality of arms supported by the shaft. The lift frame includes one or more sections supported by the plurality of arms. The one or more sections have a different transmissivity than the plurality of arms.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a partial schematic side cross-sectional view of a processing chamber, according to one or more embodiments.

FIG. 2 is a schematic partial top view of the lift frame shown in FIG. 1, according to one or more embodiments.

FIG. 3 is a schematic partial perspective view of the lift frame shown in FIG. 2, according to one or more embodiments.

FIG. 4 is schematic side cross-sectional view of a processing chamber, according to one or more embodiments.

FIG. 5 is a schematic top view of the lift frame shown in FIG. 4, according to one or more embodiments.

FIG. 6 is a schematic cross-sectional view of the lift frame along Section 6-6 shown in FIG. 5, according to one or more embodiments.

FIG. 7 is a schematic cross-sectional view of the lift frame along Section 7-7 shown in FIG. 5, according to one or more embodiments.

FIG. 8 is a schematic partial top view of a lift frame, according to one or more embodiments.

FIG. 9 is a schematic partial perspective view of the lift frame shown in FIG. 8, according to one or more embodiments.

FIG. 10 is a schematic partial perspective view of a lift frame, according to one or more embodiments.

FIG. 11 is a schematic partial top view of a ring shown in FIG. 10, according to one or more embodiments.

FIG. 12 is a partially enlarged view of the lift frame shown in FIG. 10, according to one or more embodiments.

FIG. 13 is a schematic partial perspective view of a lift frame, according to one or more embodiments.

FIG. 14 is a partially enlarged view of the lift frame shown in FIG. 13, according to one or more embodiments.

FIG. 15 is a schematic partial perspective view of a lift frame, according to one or more embodiments.

FIG. 16 is a schematic perspective view of a mass, according to one or more embodiments.

FIG. 17 is a schematic perspective view of a mass, according to one or more embodiments.

FIG. 18 is a schematic top view of the mass shown in FIG. 16 used as a plurality of masses supported by the lift frame shown in FIG. 15, according to one or more embodiments.

FIG. 19 is a schematic block diagram view of a method of substrate processing, according to one or more embodiments.

FIG. 20 is a schematic perspective view of a mass, according to one or more embodiments.

FIG. 21 is a schematic perspective view of a mass, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to a semiconductor processing chamber, and more particularly, to one or more methods of apparatuses for introducing purge gas within a processing chamber.

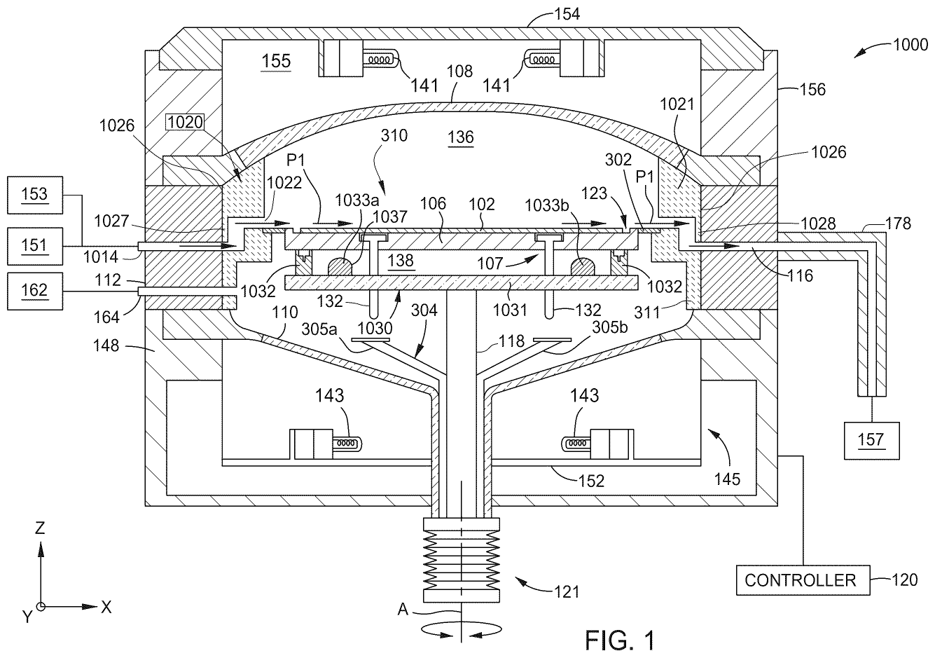

FIG. 1 is a partial schematic side cross-sectional view of a processing chamber 1000, according to one or more embodiments. The processing chamber 1000 is a deposition chamber. In one or more embodiments, the processing chamber 1000 is an epitaxial deposition chamber. The processing chamber 1000 is utilized to grow an epitaxial film on a substrate 102. The processing chamber 1000 creates a cross-flow of precursors across a top surface of the substrate 102. The processing chamber 1000 is shown in a processing condition in FIG. 1.

The processing chamber 1000 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support 106, an upper window 108 (such as an upper dome), a lower window 110 (such as a lower dome), a plurality of upper heat sources 141, and a plurality of lower heat sources 143. As shown, a controller 120 is in communication with the processing chamber 100 and is used to control processes and methods, such as the operations of the methods described herein. The present disclosure contemplates that each of the heat sources described herein can include one or more of: lamp(s), resistive heater(s), light emitting diode(s) (LEDs), and/or laser(s). The present disclosure contemplates that other heat sources can be used.

The substrate support 106 is disposed between the upper window 108 and the lower window 110. The substrate support 106 includes a support face 123 that supports the substrate 102. The plurality of upper heat sources 141 are disposed between the upper window and a lid 154. The plurality of upper heat sources 141 form a portion of the upper heat source module 155. The lid 154 may include a plurality of sensors disposed therein or thereon for measuring the temperature within the processing chamber 100. The plurality of lower heat sources 143 are disposed between the lower window 110 and a floor 152. The plurality of lower heat sources 143 form a portion of a lower heat source module 145. In one or more embodiments, the upper window 108 is an upper dome and is formed of an energy transmissive material, such as quartz. In one or more embodiments, the lower window 110 is a lower dome and is formed of an energy transmissive material, such as quartz. A pre-heat ring 302 is disposed outwardly of the substrate support 106. The pre-heat ring 302 is supported on a ledge of the lower liner 311. A stop 304 includes a plurality of arms 305a, 305b that each include a lift pin stop on which at least one of the lift pins 132 can rest when the substrate support 106 is lowered (e.g., lowered from a process position to a transfer position).

The internal volume has the substrate support 106 disposed therein. The substrate support 106 includes a top surface on which the substrate 102 is disposed. The substrate support 106 is supported by a shaft 118. The shaft 118 is connected to a motion assembly 121. The motion assembly 121 includes one or more actuators and/or adjustment devices that provide movement and/or adjustment for the shaft 118 and/or the substrate support 106.

The substrate support 106 may include lift pin perforations 107 disposed therein. The lift pin perforations 107 are sized to accommodate a lift pin 132 for lifting of the substrate 102 from the substrate support 106 either before or after a deposition process is performed. An upper liner 1020 includes an annular section 1021. The upper liner 1020 includes a first extension 1027 and a second extension 1028 disposed outwardly of the lower surface 1029 of the upper liner 1020. At least part of the annular section 1021 of the upper liner 1020 is aligned with the first extension 1027 and the second extension 1028.

The flow module 112 (which can define at least part of one or more sidewalls of the processing chamber 1000) includes one or more first inlet openings 1014 in fluid communication with the processing volume 136. The one or more first inlet openings 1014 are in fluid communication with one or more flow gaps between the upper liner 1020 and the lower liner 311. The one or more inlet openings 1014 are fluidly connected to one or more process gas sources 151 and one or more cleaning gas sources 153. The purge gas inlet(s) 164 are fluidly connected to one or more purge gas sources 162. The one or more exhaust outlets 116 are fluidly connected to an exhaust pump 157. One or more process gases supplied using the one or more process gas sources 151 can include one or more reactive gases (such as one or more of silicon-containing, boron-containing, arsenic-containing, phosphorus-containing, and/or germanium-containing gases, and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen and/or chlorine. In one or more embodiments, the one or more process gases include silicon phosphide (SiP) and/or phospine (PH₃), and the one or more cleaning gases include hydrochloric acid (HCl).

The one or more exhaust outlets 116 are further connected to or include an exhaust system 178. The exhaust system 178 fluidly connects the one or more exhaust outlets 116 and the exhaust pump 157. The exhaust system 178 can assist in the controlled deposition of a layer on the substrate 102. The exhaust system 178 is disposed on an opposite side of the processing chamber 100 relative to the flow module 112. The one or more inlet openings 114 are configured to direct a gas (such as the process gas(es) P1) across a gas flow path over the substrate support 106 and to the one or more exhaust outlets 116.

During a deposition operation (e.g., an epitaxial growth operation), the one or more process gases P1 flow through the one or more first inlet openings 1014, through the one or more gaps, and into the processing volume 136 to flow across a gas flow path over the substrate 102. During the deposition operation one or more purge gases P2 flow through the purge gas inlets 164 and into the purge volume 138, and are exhausted form the purge volume 138. The one or more purge gases P2 flow simultaneously with the flowing of the one or more process gases P1. The one or more process gases P1 are exhausted through gaps between the upper liner 1020 and the lower liner 311, and through the one or more exhaust outlets 116. The present disclosure contemplates that that one or more purge gases P2 can be exhausted through the one or more exhaust outlets 116 or can be separately exhausted through one or more second gas exhaust outlets that are separate from the one or more exhaust outlets 116.

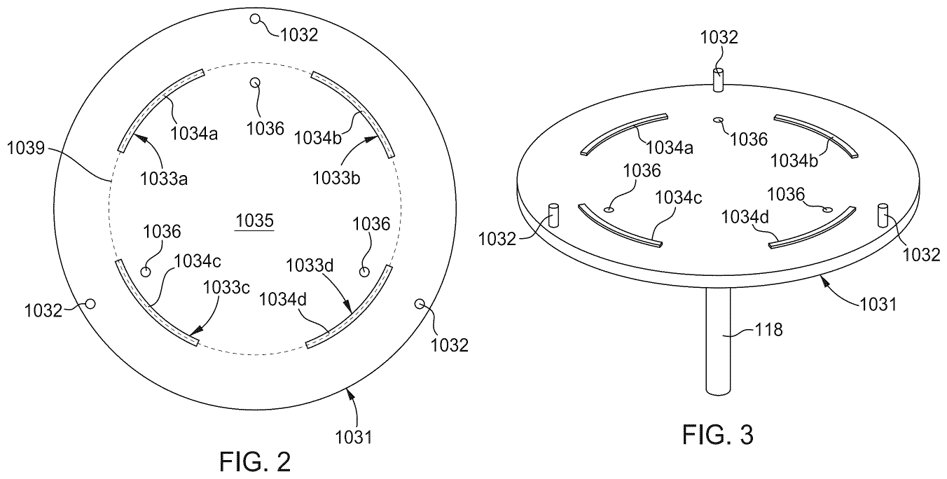

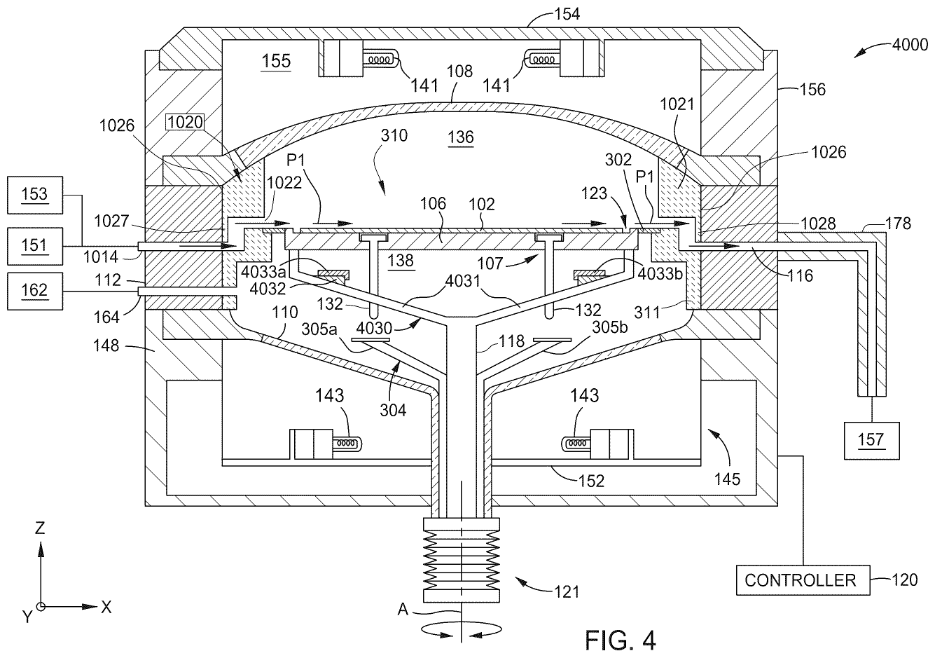

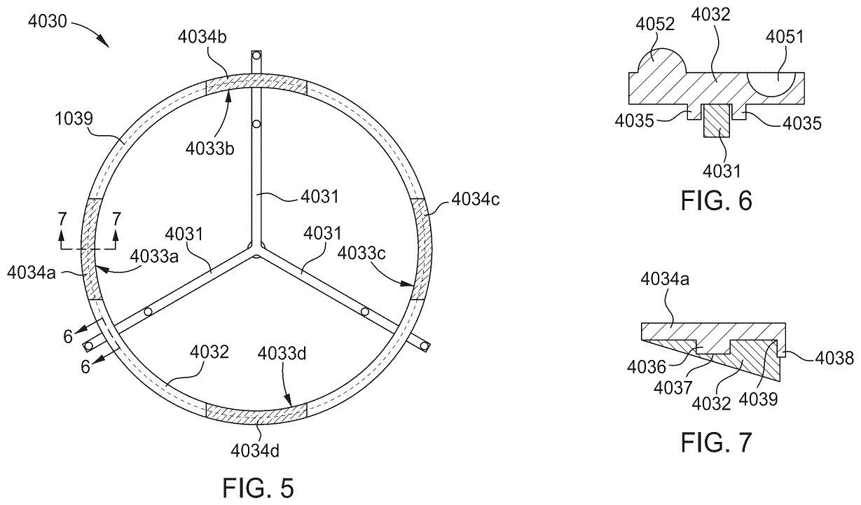

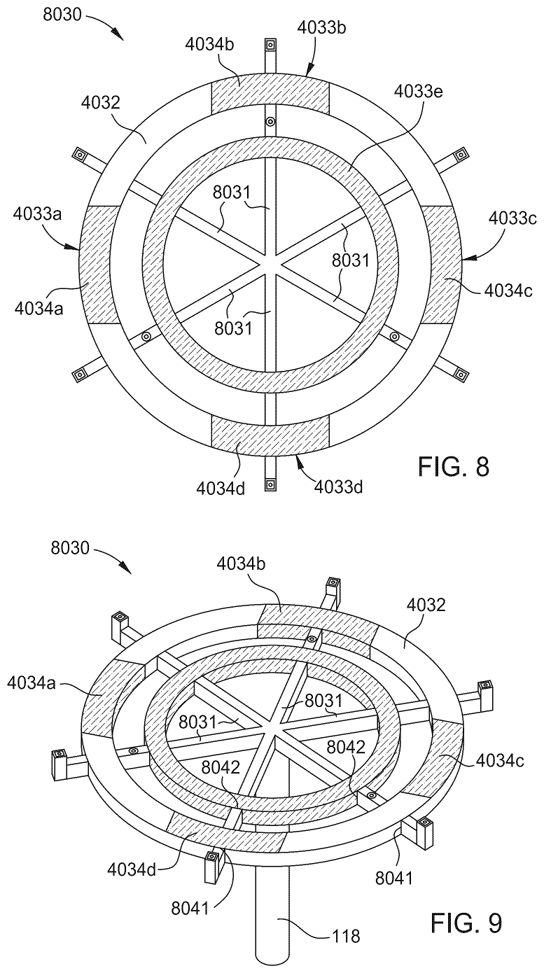

A lift frame 1030 is disposed in the purge volume 138 of the processing chamber 1000. The lift frame 1030 is part of a substrate support assembly that includes the substrate support 106. The lift frame 1030 includes the shaft 118 and a plate 1031 supported by the shaft 118. The present disclosure contemplates that a variety of lift frame structures can be used. For example, a lift frame can include a disk (as shown in FIGS. 2 and 3), three arms (a shown in FIGS. 5, 10, 13, 15, and 18), or six arms (as shown in FIGS. 8 and 9). The plate 1031 includes a first material. In one or more embodiments, the first material includes a transparent material (such as transparent quartz). In one or more embodiments, the first material is formed of the transparent material. The lift frame 1030 includes a plurality of arms 1032 extending relative to the plate 1031, and one or more sections 1033a-1033d having a different transmissivity than the plate 1031. In one or more embodiments, the second material has a lower transmissivity (and a higher absorption) than the first material, and the one or more masses 1033a-1033d are absorptive masses. In one or more embodiments, the second material has a higher transmissivity (and a lower absorption) than the first material, and the one or more masses 1033a-1033d are transmissive masses. In one or more embodiments, the second material is at least partially opaque (for example opaque to infrared energy). In one or more embodiments, the second material has an atomic structure that is non-crystalline (e.g., amorphous or polymorphous). In one or more embodiments, the second material includes silicon carbide (SiC). In one or more embodiments, the second material includes a transparent material, such as opaque quartz.

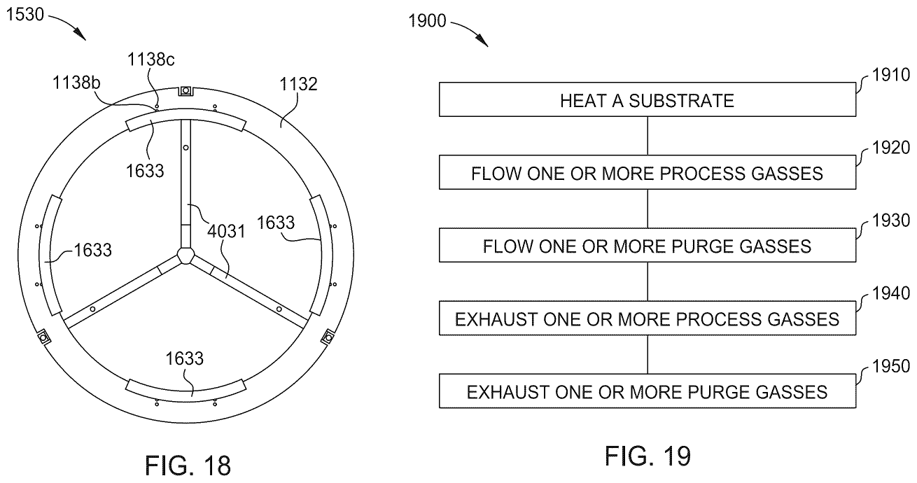

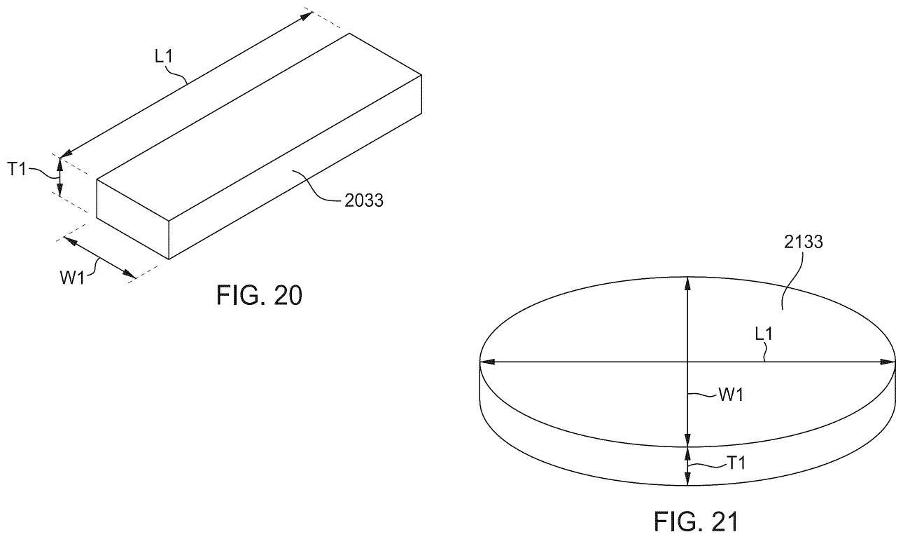

In one or more embodiments (and as shown in FIG. 1) the one or more sections 1033a-1033d include one or more masses that are supported by the plate 1031 and include the first material or a second material. In one or more embodiments, the one or more masses include a second material that is different than the first material of the plate 1031. In one or more embodiments, the one or more sections 1033a-1033d are portions of the first material (e.g., portions of the plate 1031 or portions of the rings made of the first material—as discussed below). For example, the one or more sections 1033a-1033d can be formed of the same first material but can be altered (such as to have a different surface roughness) to have a different transmissivity relative to the other sections of the first material (e.g., other sections of the plate 1031). The other one or more masses described herein can be replaced with such sections in a similar manner. As an example, the masses 4034a-4034d shown in FIGS. 5, 8, and 9, the masses 1633 shown in FIG. 18, the mass 2033 shown in FIG. 20, and/or the mass 2133 shown in FIG. 21 can be replaced with sections made of the first material that have a different transmissivity relative to the respective ring 4032, 4033e, 1132.

The present disclosure contemplates that other materials, for example opaque quartz (such as frosted quartz, white quartz, grey quartz, clear quartz impregnated with Si particles or SiC particles, and/or black quartz) can be used for the second material. In one or more embodiments, the second material includes one or more of silicon carbide (SiC), black quartz, opaque quartz, or graphite. In one or more embodiments, the second material has an atomic structure of 3C (e.g., 3C—SiC). In one or more embodiments, the atomic structure is 4H (e.g., 4H—SiC), or 6H (e.g., 6H—SiC). In one or more embodiments the one or more masses 1033a-1033d are formed of an opaque material. In one or more embodiments, the second material includes a transparent material (e.g., formed of the transparent material), such as opaque quartz. In one or more embodiments the one or more masses 1033a-1033d are formed of silicon carbide (SiC). In one or more embodiments, the first material has a first emissivity that is 0.50 or less (such as for light in the infrared range), and the second material has a second emissivity that is 0.75 or higher (such as for light in the infrared range). In one or more embodiments, the first material has a first transmissivity that is 0.80 or higher (such as for light in the infrared range), and the second material has a second transmissivity that is 0.20 or less (such as for light in the infrared range).

For visual clarity purposes, cross-sectional hatching is not shown for certain components (such as the shaft 118) in FIG. 1.

FIG. 2 is a schematic partial top view of the lift frame 1030 shown in FIG. 1, according to one or more embodiments.

FIG. 3 is a schematic partial perspective view of the lift frame 1030 shown in FIG. 2, according to one or more embodiments.

FIGS. 2 and 3 are described together. The one or more masses 1033a-1033d (a plurality are included) include a plurality of protrusions 1034a-1034d that protrude relative to an outer surface 1035 of the plate 1031. The protrusions 1034a-1034d can be curved (as shown in FIG. 1), can be linear (as shown in FIG. 20), or can be circular (as shown in FIG. 21). The plate 1031 includes a plurality of openings 1036 sized and shaped to receive shafts of the lift pins 132 therethrough. The plurality of protrusions 1034a-1034c are azimuthally spaced from each other and include a outer surface 1037 (FIG. 1) that is raised relative to the outer surface 1035 of the plate 1031. The protrusions 1034a-1034c are azimuthally spaced from each other along a circular pattern 1039. In one or more embodiments, the protrusions 1034a-1034c are respectively disposed to span part of four quadrants of the circular pattern 1039. In one or more embodiments, the protrusions 1034a-1034c are azimuthally spaced equidistantly from each other. Upper surfaces of the protrusions 1034a-1034d can be curved (as shown in FIG. 1) or can be planar (e.g., flat, as shown in FIGS. 2 and 3). The present disclosure contemplates that the protrusions (such as the protrusions 1034a-1034d) described herein can be replaced with recesses and/or indentations formed in the outer surface (such as the outer surface 1035. The present disclosure contemplates that the protrusions (such as the protrusions 1034a-1034d) described herein can be replaced with blocks of the same material disposed in recesses and/or indentations formed in the outer surface (such as the outer surface 1035. Upper surfaces of the blocks can be coplanar with the outer surface (such as the outer surface 1035.

The masses 1033a-1033d can be absorptive to absorb energy, or can be transmissive to transmit energy. The masses 1033a-1033d can focus, concentrate, and/or enhanced energy; the masses 1033a-1033d can scatter energy, reflector energy, and/or block energy. The masses 1033a-1033d can respectively have different transmissivity values. The different morphologies and/or different transmissivity values used for the respective masses 1033a-1033d can facilitate different functions.

FIG. 4 is schematic side cross-sectional view of a processing chamber 4000, according to one or more embodiments. The processing chamber 4000 is similar to the processing chamber 1000 shown in FIG. 1, and processing chamber 4000 shown in FIG. 4 includes one or more of the aspects, features, components, properties, and/or operations thereof.

A lift frame 4030 is disposed in the purge volume 138 of the processing chamber 4000. The lift frame 4030 is similar to the lift frame 1030 shown in FIG. 1, and includes one or more of the aspects, features, components, properties, and/or operations thereof. The lift frame 4030 includes a plurality of arms 4031 and a ring 4032 supported by the plurality of arms 4031. The ring 4032 includes the first material.

The lift frame 4030 includes a plurality of masses 4033a-4033d supported by the arms 4031. The plurality of masses 4033a-4033d includes a plurality of protrusions 4034a-4034d (shown in FIG. 5) azimuthally spaced from each other. The masses 4033a-4033d are supported by the ring 4032 supported by the arms 4031. The plurality of masses 4033a-4033d include the second material having a different transmissivity than the first material of the ring 4032.

FIG. 5 is a schematic top view of the lift frame 4030 shown in FIG. 4, according to one or more embodiments. The lift frame 4030 can omit the plate 1031.

FIG. 6 is a schematic cross-sectional view of the lift frame 4030 along Section 6-6 shown in FIG. 5, according to one or more embodiments. In one or more embodiments, the ring 4032 includes a plurality of shoulders 4035 for each respective arm 4031, and the respective arm 4031 is received in a recess between the shoulders 4035. The present disclosure contemplates that the masses described herein can be replaced or used with openings 4051 (shown in FIG. 6). For example, recesses can be formed in the ring 4032. Like the masses, the openings 4051 can block energy from reaching the substrate support 106. In one or more embodiments, the openings 4051 are concave. Other shapes are contemplated. The present disclosure contemplates that the plate 1031 and/or the rings herein (such as the ring 4032) can include protrusions 4052 (shown in FIG. 6). The protrusions 4052 can facilitate energy to reach the substrate support 106 to heat the substrate. The protrusions 4052 include the first material. In one or more embodiments, the protrusions 4052 are convex. Other shapes are contemplated. In FIG. 6, the protrusions 4052 and the openings 4051 are formed on an upper side of the ring 4032. Additionally or alternatively, the protrusions 4052 and/or the openings 4051 can be formed on a lower side of the ring 4032.

FIG. 7 is a schematic cross-sectional view of the lift frame 4030 along Section 7-7 shown in FIG. 5, according to one or more embodiments.

At least one of the plurality of protrusions 4034a-4034d (such as one, two, three, four, or all) includes a first extension 4036 extending into an opening 4037 (such as a recess) of the ring 4032, and a second extension 4038 extending past an edge 4039 of the ring 4032. In one or more embodiments, the edge 4039 is a radially outward edge of the ring 4032, and the second extension 4038 is disposed radially outward of the first extension 4036. The second extension 4038 can be radially inward of the first extension 4036, and the second extension 4038 can extend past a radially inward edge of the ring 4032.

FIG. 8 is a schematic partial top view of a lift frame 8030, according to one or more embodiments. The lift frame 8030 is similar to the lift frame 4030 shown in FIG. 5, and includes one or more of the aspects, features, components, properties, and/or operations thereof.

FIG. 9 is a schematic partial perspective view of the lift frame 8030 shown in FIG. 8, according to one or more embodiments.

FIGS. 8 and 9 are described together. The lift frame 8030 includes a second ring 4033e disposed radially inward of the ring 4032. The ring 4032 is a transparent ring, and the second ring 4033e is an opaque ring. In one or more embodiments, the second ring 4033e is an absorptive ring, and the second ring 4033e is an absorptive mass in addition to the masses 4033a-4033d. In one or more embodiments, the second ring 4033e is a transmissive ring, and the second ring 4033e is a transmissive mass in addition to the masses 4033a-4033d. The arms 8031 can include openings sized and shaped to receive shafts of the lift pins 132 therethrough. The ring 4032 and the second ring 4033e respectively include a plurality of recesses 8041, 8042 receiving the plurality of arms 8031 therein.

The present disclosure contemplates that complete rings are shown for the various rings described herein (such as the rings 4032, 4033e, 1132), and that one or more ring segments (such as C-rings or other incomplete rings) can be used in place of or in addition to the complete rings.

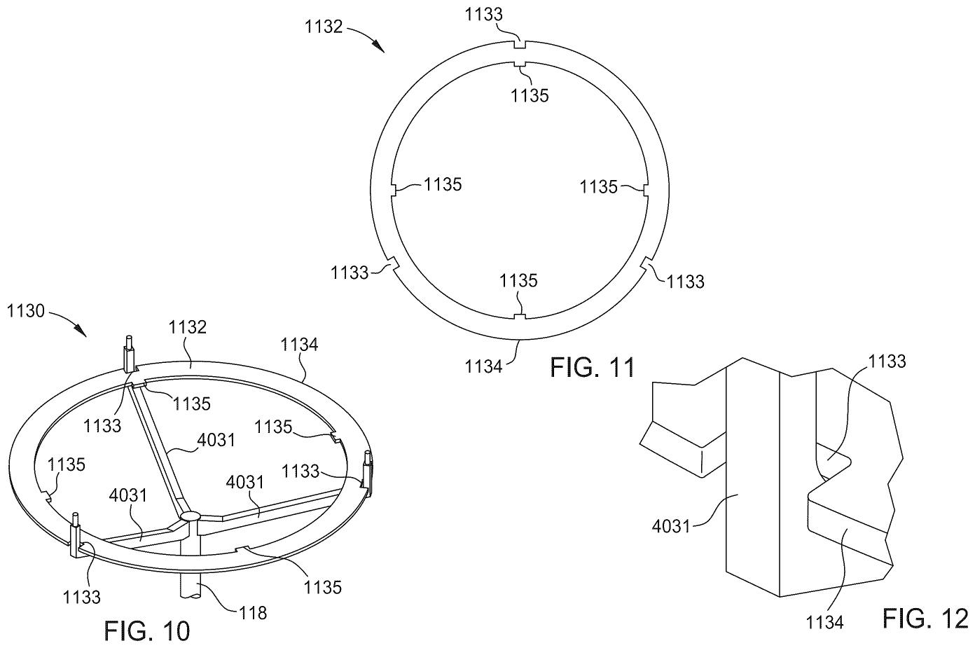

FIG. 10 is a schematic partial perspective view of a lift frame 1130, according to one or more embodiments. The lift frame 1130 is similar to the lift frame 4030 shown in FIG. 5, and includes one or more of the aspects, features, components, properties, and/or operations thereof.

FIG. 11 is a schematic partial top view of a ring 1132 shown in FIG. 10, according to one or more embodiments.

FIG. 12 is a partially enlarged view of the lift frame 1130 shown in FIG. 10, according to one or more embodiments.

FIGS. 10-12 are described together. The ring 1132 is a transparent ring and includes the first material. The masses 4033a-4033d now shown in FIGS. 10-12 are supported by the ring 1132.

The ring 1132 includes a plurality of notches 1133 formed in an outward edge 1134 of the ring 1132. The plurality of notches 1133 are sized and shaped to receive the plurality of arms 4031 therein. In one or more examples, vertical column sections of the arms 4031 are received in the notches 1133, and angled or horizontal sections of the arms 4031 support the ring 1132. The ring 1132 includes ledges 1135 extending radially inward. The ledges 1135 respectively support masses 4033a-4033d. In one or more embodiments, the ring 1132 is supported on the arms 4031 using gravity. In one or more embodiments, the ring 1132 is coupled to (such as welded, bonded, and/or fused) the arms 4031.

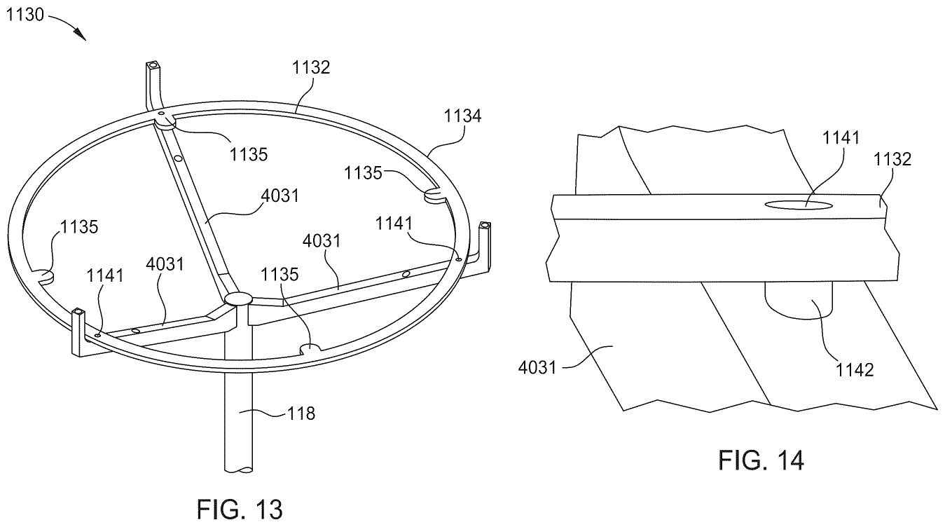

FIG. 13 is a schematic partial perspective view of a lift frame 1330, according to one or more embodiments. The lift frame 1330 is similar to the lift frame 1130 shown in FIG. 10, and includes one or more of the aspects, features, components, properties, and/or operations thereof. The ledges 1135 can be curved (such as semi-circular) in shape (as shown in FIG. 13) or rectangular (such as square) in shape (as shown in FIG. 10).

FIG. 14 is a partially enlarged view of the lift frame 1330 shown in FIG. 13, according to one or more embodiments.

FIGS. 13 and 14 are described together. In the implementation shown in FIGS. 13 and 14, the outer edge 1134 of the ring 1132 is disposed inwardly of the vertical column sections of the arms 4031. In one or more embodiments, the ring 1132 includes a plurality of openings 1141 (such as holes) sized and shaped to receive a plurality of extensions 1142 (such as pins) of the plurality of arms 4031.

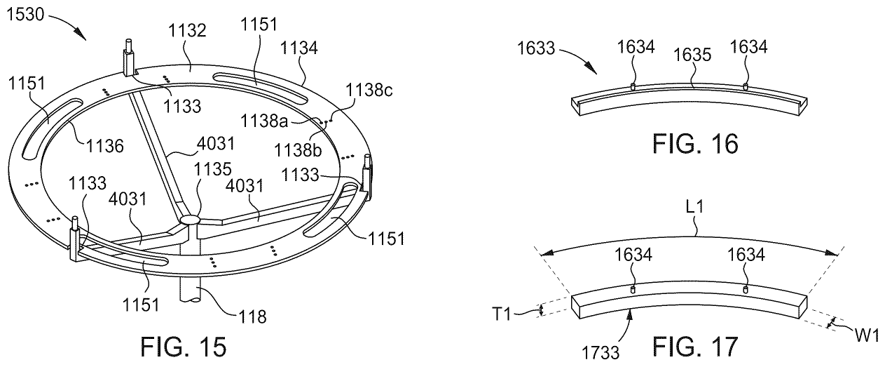

FIG. 15 is a schematic partial perspective view of a lift frame 1530, according to one or more embodiments. The lift frame 1330 is similar to the lift frame 1130 shown in FIG. 10, and includes one or more of the aspects, features, components, properties, and/or operations thereof.

The ring 1132 includes sets of openings 1138a-1138c (such as recesses or holes) arranged along a radial outward direction. The present disclosure contemplates that the plate 1031 and/or the rings herein (such as the ring 1132) can include openings, such as the openings 1138a-1138c and/or holes 1151 (shown in FIG. 15). The openings 1138a-1138c and/or holes 1151 can facilitate energy to reach the substrate support 106 to heat the substrate. The openings 1138a-1138c and/or holes 1151 can provide support (for example can receive) the first extensions 1634 shown in FIG. 16. As an example, the ring 1132 can support four masses (such as four of masses 1633). A different number of masses (such as one mass, two masses, three masses, five masses, six masses, or another number of masses) can be supported by the ring 1132.

FIG. 16 is a schematic perspective view of an mass 1633, according to one or more embodiments. The mass 1633 is a protrusion. In one or more embodiments, the protrusion is curved. Other shapes are contemplated. The mass 1633 can be linear (as shown in FIG. 20), or can be circular (as shown in FIG. 21). The mass 1633 is similar to the masses 4033a-4033d, and includes one or more of the aspects, features, components, properties, and/or operations thereof. The mass 1633 can be used in place of the respective masses 4033a-4033d.

At least one (such as one, two, three, four, or all) of the plurality of masses 1633 includes a plurality of first extensions 1634 extending into one set of the plurality of openings 1138a-1138c of the ring 1132, and a second extension 1635 extending past an inward edge 1136 of the ring 1132. In one or more embodiments, the first extensions 1634 are pins and the second extension 1635 is a shoulder.

FIG. 17 is a schematic perspective view of a mass 1733, according to one or more embodiments. The mass 1733 is similar to the mass 1633 shown in FIG. 16, and omits the second extension 1635. The mass 1733 can be used in place of the respective masses 4033a-4033d.

At least one (such as one, two, three, four, or all) of the plurality of masses 1633 has a thickness T1, a width W1, and a length L1 larger than the width W1. The length L1 is a ratio of the width W1. In one or more embodiments, the ratio is at least 1.5, such as 2.0 or higher, for example 3.0 or higher, or 4.0 or higher. The length L1 can be an arc length (such as for when the mass 1733 is a curved protrusion) or can be a linear length (such as for when the mass is a linear protrusion, for example a rectangular protrusion). In one or more embodiments, the thickness T1 is equal to or lesser than the width W1. The present disclosure contemplates that the openings and the received extensions described herein can be formed in the opposite structures. For example, one or more of the extensions 1634, 1635 can be part of the ring 1132, and one or more of the openings 1138a-1138c, 1151 can be formed in one or more of the masses 1633, 1733 FIG. 18 is a schematic top view of the mass 1633 shown in FIG. 16 used as a plurality of masses 1633 supported by the lift frame 1530 shown in FIG. 15, according to one or more embodiments.

The masses 1633 are respectively disposed such that the first extensions 1634 respectively extend into radially inward sets of openings 1138a of the ring 1132. The width W1 of the masses 1633 can be increased to cover the other sets of openings 1138b, 1138c. In one or more embodiments, the masses 1633 are supported on the arms 1633 using gravity. In one or more embodiments, the masses 1633 are coupled to (such as welded, bonded, and/or fused) the ring 1132.

FIG. 19 is a schematic block diagram view of a method 600 of substrate processing, according to one or more embodiments.

Operation 1910 includes heating a substrate positioned on a substrate support. In one more embodiments, the substrate is heated using heat sources and the substrate support is a pedestal, such as a susceptor which absorbs radiation from the heat sources and transfers thermal energy to the substrate. In one or more embodiments, the substrate is heated to a temperature within a range of 400 degrees Celsius to 1,200 degrees Celsius. Other temperatures are contemplated. During the heating of the substrate, one or more masses described herein can absorb heat to block at least some energy from heating sections of the substrate support 106 that correspond to sections of an outer region of the substrate. The blocking of the heat facilitates processing uniformity (such as film growth uniformity).

Operation 1920 includes flowing one or more process gases over the substrate to form one or more layers on the substrate. In one or more embodiments, the one or more process gases are supplied at a pressure that is 3 Torr or greater, such as within a range of 300 Torr to 600 Torr, or greater. In one or more embodiments, the one or more process gases are supplied at a flow rate that is equal to or less than 200 standard liters per minute (SLM). In one or more embodiments, the substrate is rotated at a rotation speed that is equal to or less than 120 rotations-per-minute (RPM) during the flowing of the one or more process gases over the substrate. In one or more embodiments, the rotation speed is about 16 RPM. Other pressures, flow rates, and/or rotation speeds are contemplated. The one or more process gases can flow into the processing chamber before, during, and/or after one or more of operation 1910, operation 1930, operation 1940, and/or operation 1950.

Operation 1930 includes flowing one or more purge gases into the processing chamber. The one or more purge gases can flow into the processing chamber before, during, and/or after one or more of operation 1910, operation 1920, operation 1940, and/or operation 1950.

While flowing the one or more process gases in operation 1920 and the one or more purge gases in operation 1930, the one or more process gases are thermally decomposed to form an epitaxial layer on an upper surface of a substrate.

Operation 1940 includes exhausting the one or more process gases. Operation 1940 may occur before, during, and/or after one or more of operation 1920, operation 1930, and/or operation 1950.

Operation 1950 includes exhausting the one or more purge gases. Operation 1950 may occur before, during, and/or after one or more of operation 1910, operation 1920, operation 1930, and/or operation 1940. Operation 1950 can occur simultaneously with operation 1940.

FIG. 20 is a schematic perspective view of an mass 2033, according to one or more embodiments. The mass 2033 is similar to the mass 1733 shown in FIG. 17. The mass 2033 is linear in shape. The mass 2033 can be used in place of the respective masses 4033a-4033d. FIG. 21 is a schematic perspective view of an mass 2133, according to one or more embodiments. The mass 2133 is similar to the mass 1733 shown in FIG. 17. The mass 2133 is circular in shape, such as in the shape of a disc (as shown), a semi-sphere (for example a hemi, or a sphere. The mass 2133 can be used in place of the respective masses 4033a-4033d.

Benefits of the present disclosure include enhanced temperature uniformity and deposition uniformity; gas savings; heating savings; enhanced deposition thicknesses; enhanced processing uniformities; and increased throughput and efficiency. Benefits also include modularity for adjusting temperatures and deposition growth rates. For example, a lift frame can be retrofit with a ring described herein (such as the ring 1132 shown in FIG. 15), and masses described herein (such as the masses 1633 shown in FIG. 18) can respectively be installed and removed on and from the ring to adjust temperatures and growth rates of various regions of the substrate. As an example, the masses can be installed and removed without altering the design of the substrate support 106, which modularly adjusts temperatures and growth rates with reduced or eliminated processing interference.

It is contemplated that one or more aspects disclosed herein may be combined. As an example, one or more aspects, features, components, operations and/or properties of the processing chamber 1000, the lift frame 1030, the plate 1031, the mass(es) 1033a-1033d, the processing chamber 4000, the lift frame 4030, the mass(es) 4033a-4033d, the ring 4032, the lift frame 8030, the second ring 4033e, the lift frame 1130, the ring 1132, the lift frame 1530, the mass(es) 1633, the mass(es) 1733, and/or the method 1900 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber, comprising:
a chamber body comprising a plurality of gas inject passages formed in the chamber body, the chamber body at least partially defining an internal volume; and
a substrate support assembly positioned in the internal volume, the substrate support assembly comprising a lift frame, the lift frame comprising:
a plurality of arms,
a ring supported by the plurality of arms, and
a plurality of sections on the ring, the plurality of sections azimuthally spaced from each other, and the plurality of sections having a different transmissivity than the ring.

2. The processing chamber of claim 1, wherein the ring is transparent and comprises a plurality of notches formed in an outward edge of the ring, and the plurality of notches are sized and shaped to receive the plurality of arms.

3. The processing chamber of claim 2, wherein the plurality of sections include a plurality of masses supported by the ring, and at least one of the plurality of masses comprises a plurality of first extensions extending into a plurality of openings of the ring.

4. The processing chamber of claim 3, wherein the at least one of the plurality of masses further comprises a second extension extending past an inward edge of the ring.

5. The processing chamber of claim 1, wherein the ring comprises a first material that includes a transparent quartz and the plurality of sections comprise a second material that includes one or more of silicon carbide (SiC), black quartz, opaque quartz, or graphite.

6. A lift frame for positioning in a processing chamber, comprising:
a shaft;
a plate supported by the shaft;
a plurality of arms extending relative to the plate; and
one or more sections on the plate, the one or more sections having a different transmissivity than the plate.

7. The lift frame of claim 6, wherein the one or more sections comprise a plurality of curved protrusions supported by the plate.

8. The lift frame of claim 7, wherein the plurality of curved protrusions are azimuthally spaced from each other and comprise a curved outer surface that is raised relative to the plate.

9. The lift frame of claim 6, wherein the plate comprises a first material that includes a transparent quartz and has a first transmissivity, the one or more sections include one or more masses comprising a second material that includes one or more of silicon carbide (SiC), black quartz, opaque quartz, or graphite, and the second material has a second transmissivity lower than the first transmissivity.

10. The lift frame of claim 6, wherein:
the plate comprises a first material has a first emissivity that is 0.50 or less at 1,000 degrees Celsius; and
the one or more sections include one or more masses comprising a second material has a second emissivity that is equal to or greater than 0.75 at 1,000 degrees Celsius.

11. A lift frame for positioning in a processing chamber, comprising:
a shaft;
a plurality of arms supported by the shaft; and
one or more sections supported by the plurality of arms, the one or more sections having a different transmissivity than the plurality of arms.

12. The lift frame of claim 11, wherein the one or more sections comprise:
an absorptive ring supported by the plurality of arms, the absorptive ring comprising a plurality of recesses receiving the plurality of arms.

13. The lift frame of claim 12, further comprising a transparent ring supported by the plurality of arms, wherein the one or more sections further comprise a plurality of protrusions supported by the transparent ring, wherein the plurality of protrusions are spaced azimuthally from each other.

14. The lift frame of claim 11, further comprising a transparent ring supported by the plurality of arms, wherein the one or more sections comprise a plurality of protrusions supported by the transparent ring, wherein the plurality of protrusions are spaced azimuthally from each other.

15. The lift frame of claim 14, wherein at least one of the plurality of protrusions comprises:
a first extension extending into an opening of the transparent ring; and
a second extension extending past an edge of the transparent ring.

16. The lift frame of claim 15, wherein the second extension is disposed radially outward of the first extension.

17. The lift frame of claim 14, wherein at least one of the one or more sections has a width and a length larger than the width.

18. The lift frame of claim 17, wherein the length is a ratio of the width, and the ratio is at least 1.5.

19. The lift frame of claim 14, wherein the transparent ring comprises a plurality of notches formed in an outward edge of the transparent ring, and the plurality of notches are sized and shaped to receive the plurality of arms.

20. The lift frame of claim 14, wherein the transparent ring comprises a plurality of openings sized and shaped to receive a plurality of extensions of the plurality of arms.
